(19) United States
(12) Patent Application Publication
(10) Pub. No.: US 2003/0096173 A1
(43) Pub. Date: May 22, 2003

(54) Mask structure and fabricating process thereof

(76) Inventors: Jiang-Fu Kao, Kaohsiung (TW); Jui-Tsen Huang, Taipei (TW)

Correspondence Address: CHARLES C.H. WU & ASSOCIATES, 7700 IRVINE CENTER DRIVE, Suite 710, Irvine, CA, 92618-3043, US

(21) Appl. No.: 10/034,559

(22) Filed: Dec. 26, 2001

(30) Foreign Application Priority Data
Nov. 19, 2001 (TW) 90128571

(51) Int. Cl. G03F 9/00; G03C 5/00

(52) U.S. Cl. 430/5; 430/322; 430/324

(57) ABSTRACT

A mask structure comprises a transparent substrate, a cover layer formed on the transparent substrate, and a transparent conductive thin film, with which the cover layer and the transparent substrate is covered, wherein the cover layer is provided with exposure patterns. Moreover, a process of fabricating a mask compring the steps of forming a cover layer provided with exposure patterns on a transparent substrate and then covering the transparent substrate and the cover layer uniformly with a transparent conductive thin film.

### CROSS-REFERENCE TO RELATED APPLICATION

This application claims the priority benefit of Taiwan application serial no. 90128571, filed Nov. 19, 2001.

### BACKGROUND OF THE INVENTION

1. Field of the Invention

The invention relates in general to a mask structure and a fabricating process thereof More particularly, the invention relates to a mask structure of protecting static electricity from discharge and a fabricating process thereof

2. Description of the Related Art

In general, a semiconductor process is divided into four modules comprising a diffusion module, a etching module, a thin-film module and a photo module. The photo module refers to a photolithography process, by which patterns on a mask can be transferred onto a wafer such that desirable etching patterns are provided for the etching module or desirable implant patterns are provided for the thin-film module. Therefore, quality of a photolithography process and a mask affects that of a semiconductor process.

In generally, a main body of a mask consists of a nonconductive quartz substrate and a chromium layer provided with exposure patterns. As a result, when an external electric filed is applied to the mask, it is possible that electrostatic charge is generated in the chromium layer and a phenomenon of electric charge polarization occurs.

With enhancement of concentration of integrated circuits, density of exposure patterns on a mask rises, which thus a pitch, between bit lines, between word lines, even between implant regions and between capacitors, decreases substantially. When a space between exposure patterns minimizes, electrostatic charge generated in a chromium layer leads to occurrence of electron static discharge (ESD).

Because the occurrence of electron static discharge accompanies a release of high energy with high temperature, the chromium layer on the mask can be melted due to high temperature. As a result, exposure patterns constructed out of the chromium layer are deformed and an exposure results are relatively bad.

### SUMMARY OF THE INVENTION

Accordingly, it is an objective, according to the present invention, to provide a mask structure with protecting occurrence of electric charge accumulation and that of electron static discharge.

To achieve the foregoing and other objects, the present invention provides a mask structure with a transparent substrate, a cover layer formed on the transparent substrate, and a transparent conductive thin film, with which the cover layer and the transparent substrate is covered, wherein the cover layer is provided with exposure patterns.

Moreover, the present invention provides a fabricating process of a mask. The fabricating process of a mask comprises the step of forming a cover layer provided with exposure patterns on a transparent substrate. Next, the transparent substrate and the cover layer are uniformly covered with a transparent conductive thin film.

In addition, the present invention provides a mask structure with a transparent substrate, a transparent conductive thin film formed on the transparent substrate, and, a cover layer formed on the transparent conductive thin film, wherein the cover layer is provided with exposure patterns.

Besides which, the present invention provides a fabricating process of a mask. The fabricating process of a mask comprises the step of forming a transparent conductive thin film on a transparent substrate. Next, a cover layer provided with exposure patterns is formed on the transparent conductive thin film.

Moreover, in the above present invention, the mask structure and the fabricating process thereof further comprise a ground line connected to an edge of the transparent conductive thin film.

In the mask structure of the present invention, the cover layer provided with exposure pattern is connected to the transparent conductive thin film, so electrostatic charge generated on the cover layer can pass from the cover layer via the transparent conductive thin film and the ground line to leave out of the mask. Therefore, it is effective that the mask can be prevented from the effect of electron static discharge.

Both the foregoing general description and the following detailed description are meant to be of a exemplary and explanatory nature only, and are not bound by the restrictive definition of the invention as claimed.

### BRIEF DESCRIPTION OF THE DRAWINGS

The accompanying drawings are included to provide a further understanding of the invention, and are incorporated in, and constitute a part of, this specification. The drawings illustrate the embodiments of the invention and, together with the description, serve to explain the principles of the invention. A simple description of the drawings is as follows.

FIGS. 1-3 show schematic views of a fabricating process of a mask according to a first preferred embodiment of the present invention.

FIGS. 4-5 show schematic views of a fabricating process of a mask according to a second preferred embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

First Preferred Embodiment

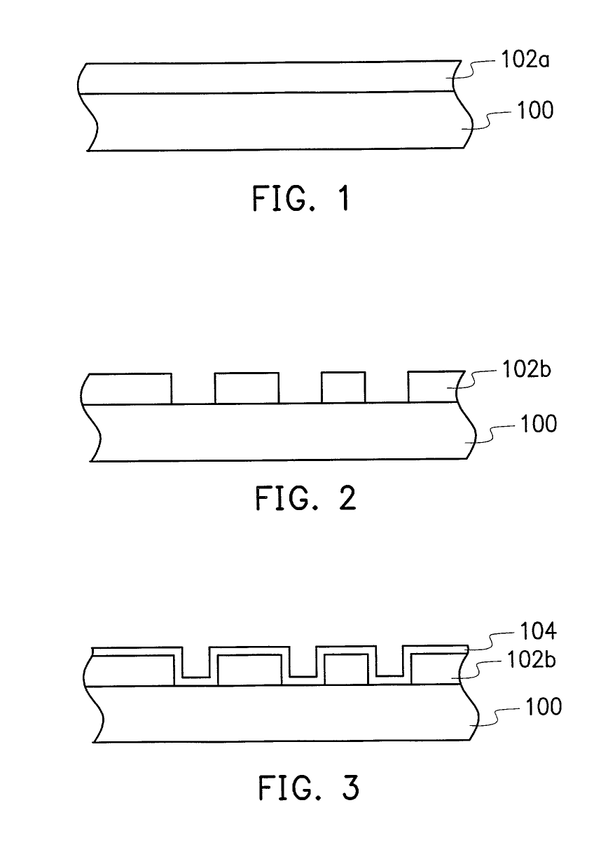

FIGS. 1-3 show schematic views of a fabricating process of a mask according to a first preferred embodiment of the present invention. Referring to FIG. 1, a transparent substrate 100 is provided and a sputtering process is applied to form a cover layer 102a on the transparent substrate 100. The transparent substrate 100 can be made of, for instance, quartz and the cover layer 102a is made of, for example, chromium. Moreover, though quartz is exemplified, material of the transparent substrate 100 is not limited and can also be calcium fluoride (CaF₂). Though a sputtering process is exemplified, a process of forming the cover layer 102a is not limited and can also bea chemical-vapor-deposition process or another physical-vapor-deposition process.

Next, as shown in FIG. 2, a laser carving process is applied to carve exposure patterns on the cover layer 102a such that a cover layer 102b provided with exposure patterns is formed. Though a laser carving process is exemplified, a process of forming exposure patterns is not limited and can also be another conventional process.

Subsequently, referring to FIG. 3, a sputtering process is applied uniformly to cover the transparent substrate 100 and the cover layer 102b with a transparent conductive thin film 104, wherein the transparent conductive thin film 104 is made, for instance, of palladium aluminum oxide (PaAl₂O₃). Though palladium aluminum oxide (PaAl₂O₃) is exemplified, material of the transparent conductive thin film 104 is not limited and can also be other conductive and transparent material. In addition, though a sputtering process is exemplified, a process of forming the transparent conductive thin film 104 is not limited and can also be a chemical-vapor-deposition process or another physical-vapor-deposition process.

In summary, a mask structure of the present invention comprises at least a transparent substrate 100, a cover layer 102b formed on the transparent substrate 100, and a transparent conductive thin film 104, with which the cover layer 102b and the transparent substrate 100 is covered.

Moreover, an edge of the transparent conductive thin film 104 can be electrically connected to a ground line (not shown). As a result, electric charge generated on the transparent conductive thin film 104 can pass by the ground line to leave out of the mask.

Accordingly, the transparent conductive thin film 104 is electrically connected to the cover layer 102b, so, when induced electric charge is generated on surface of the cover layer 102b with an external electric field applied, the electric charge can pass from the cover layer 102b to the transparent conductive thin film 104 and then pass to the ground line connected to the transparent conductive thin film 104 to leave out of the mask. Therefore, it is effective that accumulating electric charge in the cover layer 102b can be prevented and the mask can be prevented from the effect of electron static discharge

Second Preferred Embodiment

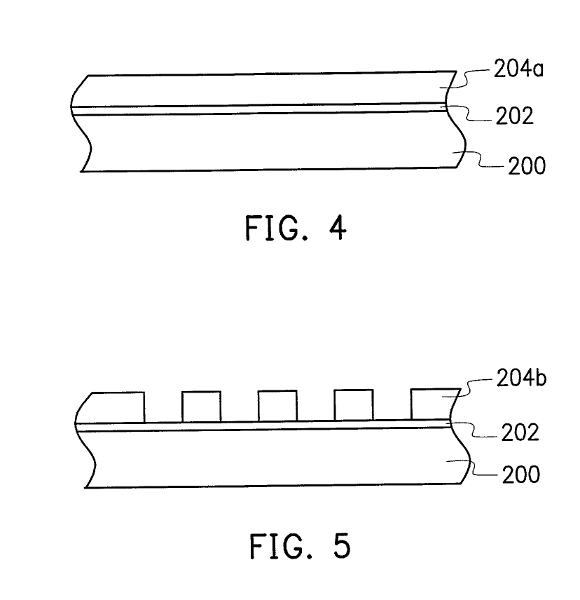

FIGS. 4-5 show schematic views of a fabricating process of a mask according to a second preferred embodiment of the present invention. Referring to FIG. 1, a transparent substrate 200 is provided and a sputtering process is applied to form a transparent conductive thin film 202 on the transparent substrate 200. The transparent substrate 200 can be made of, for instance, quartz and the transparent conductive thin film 202 is made of, for instance, of palladium aluminum oxide (PaAl₂O₃). Though palladium aluminum oxide (PaAl₂O₃) is exemplified, material of the transparent conductive thin film 202 is not limited and can also be other conductive and transparent material. Though a sputtering process is exemplified, a process of forming the transparent conductive thin film 202 is not limited and can also be a chemical-vapor-deposition process or another physical-vapor-deposition process. Moreover, through quartz is exemplified, material of the transparent substrate 200 is not limited and can also be calcium fluoride (CaF₂).

Next, a sputtering process is applied to form a cover layer 204a on the transparent substrate 200, wherein the cover layer 204a is made of, for example, chromium. Though a sputtering process is exemplified, a process of forming the cover layer 204a is not limited and can also be a chemical-vapor-deposition process or another physical-vapor-deposition process.

Subsequently, a laser carving process is applied to carve exposure patterns on the cover layer 204a so that a cover layer 204b provided with exposure patterns is formed. Though a laser carving process is exemplified, a process of forming exposure patterns is not limited and can also be another conventional process.

In summary, a mask structure of the present invention comprises at least a transparent substrate 200, a transparent conductive thin film 202 formed on the transparent substrate 200, and, a cover layer 204b formed on the transparent conductive thin film 202, wherein the cover layer 204b is provided with exposure patterns.

Moreover, an edge of the transparent conductive thin film 202 can be electrically connected to a ground line (not shown). As a result, electric charge generated on the transparent conductive thin film 202 can pass by the ground line to leave out of the mask.

Accordingly, the transparent conductive thin film 202 is electrically connected to the cover layer 204b, so, when induced electric charge is generated on surface of the cover layer 204b with an external electric field applied, the electric charge can pass from the cover layer 204b to the transparent conductive thin film 202 and then pass to the ground line connected to the transparent conductive thin film 202 to leave out of the mask. Therefore, it is effective that accumulating electric charge in the cover layer 204b can be prevented and the mask can be prevented from the effect of electron static discharge.

It will be apparent to those skilled in the art that various modifications and variations can be made to the structure of the present invention without departing from the scope or spirit of the invention. In view of the foregoing, it is intended that the present invention cover modifications and variations of this invention provided that they fall within the scope of the following claims.

What is claimed is:

1. A mask structure, comprising:
a transparent substrate;
a cover layer, formed on the transparent substrate and provided with exposure patterns; and
a transparent conductive thin film, with which the cover layer and the transparent substrate is covered.

2. The mask structure according to claim 1, wherein the mask structure further comprises a ground line connected to an edge of the transparent conductive thin film.

3. The mask structure according to claim 1, wherein the transparent conductive thin film is made of palladium aluminum oxide.

4. The mask structure according to claim 1, wherein the cover layer is made of chromium.

5. The mask structure according to claim 1, wherein the transparent substrate can be made of quartz.

6. The mask structure according to claim 1, wherein the transparent substrate is made of calcium fluoride.

7. A process of fabricating a mask, comprising the steps of forming a cover layer provided with exposure patterns on a transparent substrate; and
covering the transparent substrate and the cover layer uniformly with a transparent conductive thin film.

8. The process of fabricating a mask according to claim 7, wherein a ground line connected to an edge of the transparent conductive thin film.

9. The process of fabricating a mask according to claim 7, wherein the transparent conductive thin film is made of palladium aluminum oxide.

10. A mask structure, comprising:
a transparent substrate,
a transparent conductive thin film formed on the transparent substrate; and
a cover layer, formed on the transparent conductive thin film and provided with exposure patterns.

11. The mask structure according to claim 10, wherein the mask structure further comprises a ground line connected to an edge of the transparent conductive thin film.

12. The mask structure according to claim 10, wherein the transparent conductive thin film is made of palladium aluminum oxide.

13. The mask structure according to claim 10, wherein the cover layer is made of chromium.

14. The mask structure according to claim 10, wherein the transparent substrate can be made of quartz.

15. The mask structure according to claim 10, wherein the transparent substrate is made of calcium fluoride.

16. A process of fabricating a mask, comprising the steps of:
forming a transparent conductive thin film on a transparent substrate; and
forming a cover layer provided with exposure patterns on the transparent conductive thin film.

17. The process of fabricating a mask according to claim 16, wherein a ground line connected to an edge of the transparent conductive thin film.

18. The process of fabricating a mask according to claim 16, wherein the transparent conductive thin film is made of palladium aluminum oxide.
